(19) United States
(12) Patent Application Publication
(10) Pub. No.: US 2015/0235872 A1
(43) Pub. Date: Aug. 20, 2015

(54) Curable Silicone Composition, Method For Producing Semiconductor Device, And Semiconductor Device

(71) Applicant: DOW CORNING TORAY CO., LTD., Tokyo (JP)

(72) Inventors: Hiroaki Yoshida, Ichihara-shi (JP); Yusuke Miyamoto, Ichihara-shi (JP); Makoto Yoshitake, Ichihara-shi (JP); Shin Yoshida, Ichihara-shi (JP)

(21) Appl. No.: 14/426,890

(22) PCT Filed: Sep. 6, 2013
(86) PCT No.: PCT/JP2013/074781

§ 371 Date: Mar. 9, 2015

(30) Foreign Application Priority Data
Sep. 10, 2012 (JP) 2012-198803

(51) Int. Cl. H01L 21/56; H01L 21/78; B29C 43/18; B29C 43/00; B29C 43/20; H01L 23/29; C09J 143/04

(52) U.S. Cl. CPC H01L 21/565; H01L 23/296; H01L 21/78; C09J 143/04; B29C 43/003; B29C 43/203; B29C 43/18; B29C 2043/182; B29L 2009/005

(57) ABSTRACT

The present invention relates to a curable silicone composition comprising: (A) an organopolysiloxane composed of: (A-1) a linear organopolysiloxane having at least two silicon-bonded alkenyl groups in a molecule, and (A-2) a resin-like organopolysiloxane including 1.5 to 5.0% by weight alkenyl groups; (B) an organopolysiloxane having at least two silicon-bonded hydrogen atoms in a molecule; (C) a linear dialkyl polysiloxane having a viscosity at 25° C. of 2 to 10 mm²/s and having alkenyl groups capping both molecular chain terminals; and (D) a hydrosilylation reaction catalyst. The curable silicone composition forms a cured product having low surface tackiness and a low coefficient of friction.

### TECHNICAL FIELD

The present invention relates to a curable silicone composition, a method for producing a semiconductor device utilizing this composition, and a semiconductor device obtained by this method.

Priority is claimed on Japanese Patent Application No. 2012-198803, filed on Sep. 10, 2012, the content of which is incorporated herein by reference.

### BACKGROUND ART

Curable silicone compositions composed of dimethylpolysiloxane as a main component are used for various types of applications due to forming a cured product that has excellent rubber-like properties (i.e. hardness, elongation, or the like) and has characteristics such as weather resistance, heat resistance, or the like. Curable silicone compositions are particularly used as sealing agents for semiconductor devices due to the formation of a transparent cured product that has low refractive index. However, there have been problems in that tackiness of the surface of this cured product is high, so dust readily adheres to the semiconductor device sealed by the curable silicone composition, and cuttings readily adhere to a semiconductor device obtained as an individual semiconductor device by dicing in the blade dicing step for a semiconductor device sealed by this cured product. Moreover, there has also been a problem of worsening of handling and processability due to adhesion of the diced semiconductor devices to each other.

Japanese Unexamined Patent Application Publication Nos. 2009-052038 and 2010-174234 propose a curable silicone composition for formation of a highly transparent cured product that has a high refractive index and that has no surface stickiness, where the composition comprises: (A) an organopolysiloxane composed of (A-1) a dialkyl polysiloxane having silicon-bonded alkenyl groups, and (A-2) a resin-like organopolysiloxane having silicon-bonded alkenyl groups; (B) an organopolysiloxane having silicon-bonded hydrogen atoms and having alkenyl groups with 1 to 10 carbon atoms as silicon-bonded groups other than hydrogen atoms; and (C) a hydrosilylation reaction catalyst.

However, when a semiconductor device was sealed using the curable silicone compositions mentioned respectively in the Patent Documents, it was found that there were problems in that dust readily adhered to the obtained semiconductor device, and the semiconductor devices adhered to each other so that later handling and processability was poor.

An object of the present invention is to provide a curable silicone composition that forms a cured product having low surface tackiness and a small friction coefficient. Another object of the present invention is to provide a method for producing a semiconductor device that is resistant to adhesion of dust and resistant to semiconductor devices sticking together, and to provide such a semiconductor device.

### DISCLOSURE OF INVENTION

The curable silicone composition of the present invention comprises:
(A) 100 parts by mass of an organopolysiloxane composed of:
   (A-1) 30 to 70% by mass of a linear organopolysiloxane having a viscosity at 25° C. of 10 to 100,000 mPa·s, having at least two silicon-bonded alkenyl groups in a molecule, and each silicon-bonded group other than alkenyl group being independently selected from alkyl groups with 1 to 10 carbon atoms, and
   (A-2) 70 to 30% by mass of a resin-like organopolysiloxane having 1.5 to 5.0% by mass of alkenyl groups, and comprising SiO_{4/2} units, R¹₂R²SiO_{1/2} units, and R¹₃SiO_{1/2} units, wherein each R¹ is independently a group selected from alkyl groups with 1 to 10 carbon atoms, and R² is an alkenyl group;
(B) an organopolysiloxane having at least two silicon-bonded hydrogen atoms in a molecule, and each silicon-bonded group other than hydrogen atom being independently selected from alkyl groups with 1 to 10 carbon atoms, in an amount such that the content of of silicon-bonded hydrogen atoms contained in component (B) to 1 mole of total alkenyl groups contained in component (A) is in the range of 0.5 to 5 moles;
(C) 0.5 to 12 parts by mass of a linear dialkyl polysiloxane having a viscosity at 25° C. of 2 to 10 mm²/s and having alkenyl groups capping both molecular chain terminals; and
(D) a catalytic amount of hydrosilylation reaction catalyst.

The method for producing a semiconductor device of the present invention includes a step of sealing a semiconductor element by the aforementioned curable silicone composition.

Furthermore, the semiconductor device of the present invention is obtained by the aforementioned method.

### EFFECTS OF THE INVENTION

The curable silicone composition of the present invention is characterized as forming a cured product that has low surface tackiness and a low friction coefficient. Moreover, the method for producing the semiconductor device of the present invention is characterized in that the method is able to manufacture with good efficiency semiconductor devices that are resistant to the adhesion of dust and that are resistant to the adhesion of each other. Furthermore, the semiconductor device of the present invention is characterized in that the semiconductor devices are resistant to the adhesion of dust and are resistant to the adhesion of each other.

### BRIEF DESCRIPTION OF THE DRAWINGS

FIG. 1 is a partial cross-sectional drawing of the semiconductor devices prior to sealing by the curable silicone composition.

FIG. 2 is partial cross-sectional drawing showing conditions prior to using the curable silicone composition to fill the mold.

FIG. 3 is a partial cross-sectional drawing showing conditions after using the curable silicone composition to fill the mold.

FIG. 4 is a partial cross-sectional drawing showing compression molding of the curable silicone composition.

FIG. 5 is a partial cross-sectional drawing of the semiconductor devices integrated with the cured product.

FIG. 6 is a partial cross-sectional drawing of other semiconductor devices integrated with the cured product.

FIG. 7 is a partial cross-sectional drawing of further other semiconductor devices integrated with the cured product.

### DETAILED DESCRIPTION OF THE INVENTION

First, the curable silicone composition of the present invention will be explained in detail.

An organopolysiloxane for component (A) is a main component of the present composition, and is composed of: (A-1) 30 to 70% by mass of a linear organopolysiloxane having a viscosity at 25° C. of 10 to 100,000 mPa·s, having at least two silicon-bonded alkenyl groups in a molecule, and each silicon-bonded group other than alkenyl group being independently selected from alkyl groups with 1 to 10 carbon atoms; and (A-2) 70 to 30% by mass of a resin-like organopolysiloxane having 1.5 to 5.0% by mass of alkenyl groups and comprising SiO_{4/2} units, R¹₂R²SiO_{1/2} units, and R¹₃SiO_{1/2} units, in the formulae, each R¹ is independently a group selected from alkyl groups with 1 to 10 carbon atoms, and R² is an alkenyl group.

Component (A-1) is a component for imparting plasticity to the cured product of the present composition. The alkenyl group in component (A-1) is exemplified by a vinyl group, allyl group, isopropenyl group, butenyl group, hexenyl group, and cyclohexenyl group. The alkenyl group in component (A-1) is preferably an alkenyl group having 2 to 10 carbon atoms, and particularly preferably is a vinyl group. No particular limitation is placed on the bonding position of this alkenyl group in the linear polyorganosiloxane. This alkenyl group may be bonded to either a silicon atom at the molecular chain terminus or to a silicon atom in the molecular chain, or these alkenyl groups may be bonded to both silicon atoms at the molecular chain terminus and to silicon atoms in the molecular chain. The alkyl group in component (A-1) is exemplified by a methyl group, ethyl group, propyl group, cyclopentyl group, cyclohexyl group, or a similar alkyl group having 1 to 10 carbon atoms. The alkyl group in component (A-1) is preferably a methyl group. Although the molecular structure of component (A-1) is preferably substantially linear, part of the molecular chain may be somewhat branched.

A viscosity at 25° C. of component (A-1) is within the range of 10 to 100,000 mPa·s, preferably is within the range of 20 to 10,000 mPa·s, and particularly preferably is in the range of 40 to 3,000 mPa·s. When the viscosity at 25° C. of component (A-1) is greater than or equal to the lower limit of the aforementioned range, a cured product is obtained that has the desired flexibility. On the other hand, when the viscosity at 25° C. of component (A-1) is less than the upper limit of the aforementioned range, a composition is obtained that has good handling and processability.

This type of component (A-1) is exemplified by polydimethylsiloxane having dimethylvinylsiloxy groups capping both molecular chain terminals, dimethylsiloxane-methylvinylsiloxane copolymer having dimethylvinylsiloxy groups capping both molecular chain terminals, methylvinylpolysiloxane having trimethylsiloxy groups capping both molecular chain terminals, dimethylsiloxane-methylvinylsiloxane copolymer having trimethylsiloxy groups capping both molecular chain terminals, and mixtures of two or more such compounds.

Component (A-2) is a component for imparting adhesion to the substrate and strength to the cured product of the present composition, and is a resin-like organopolysiloxane composed of SiO_{4/2} units, R¹₂R²SiO_{1/2} units, and R¹₃SiO_{1/2} units. In the formulae, each R¹ is independently a group selected from alkyl groups having 1 to 10 carbon atoms, as exemplified by a methyl group, ethyl group, propyl group, cyclopentyl group, cyclohexyl group, or the like. In the formula, each R² is independently an alkenyl group such as a vinyl group, allyl group, isopropenyl group, butenyl group, hexenyl group, cyclohexenyl, or the like. R² is further preferably a group selected from alkenyl groups having 2 to 10 carbon atoms, and particularly preferably is a vinyl group. Component (A-2) includes 1.5 to 5.0% by mass of alkenyl groups, and preferably includes 2.0 to 4.0% by mass of alkenyl groups. When the content of alkenyl groups in component (A-2) is greater than or equal to the lower limit of the aforementioned range, the obtained cured product may have the desired high hardness. On the other hand, the obtained cured product has the desired flexibility when this content of alkenyl groups is less than or equal to the upper limit of the aforementioned range. The expression “% by mass of the alkenyl groups” refers to % by mass of the total component that is alkenyl groups as calculated after conversion to the vinyl group (CH₂═CH—).

Moreover, although no particular limit is placed on the total number of moles of the R¹₂R²SiO_{1/2} units and R¹₃SiO_{1/2} units relative to 1 mole of the SiO_{4/2} units in component (A-2), this number is preferably in the range of 0.5 to 1.4, further preferably is in the range of 0.6 to 1.3, and particularly preferably is in the range of 0.7 to 1.2. When the total number of moles of the R¹₂R²SiO_{1/2} units and R¹₃SiO_{1/2} units relative to 1 mole of the SiO_{4/2} units is greater than or equal to the lower limit of the aforementioned range, a composition is obtained that has preferred handling and processing ability. On the other hand, when the total number of moles of the R¹₂R²SiO_{1/2} units and R¹₃SiO_{1/2} units relative to 1 mole of the SiO_{4/2} units is less than or equal to the upper limit of the aforementioned range, a cured product is obtained that has preferred flexibility.

Although no particular limitation is placed on molecular weight of component (A-2), the mass average molecular weight converted to standard polystyrene and determined by gel permeation chromatography is preferably in the range of 3,000 to 7,000, and further preferably is in the range of 4,000 to 6,000. Moreover, component (A-2) may be a mixture of two or more types of organopolysiloxanes. When component (A-2) is a mixture of two or more types of organopolysiloxanes, the average value of the mass average molecular weight converted to standard polystyrene as determined by gel permeation chromatography is preferably within the aforementioned range.

Component (A) is composed of 30 to 70% by mass of component (A-1) and 70 to 30% by mass of component (A-2), and preferably is composed of 35 to 65% by mass of component (A-1) and 35 to 65% by mass of component (A-2). When the content of component (A-1) is greater than or equal to the lower limit of the aforementioned range, a composition is obtained that has good handling and processing ability. On the other hand, a cured product having good flexibility is obtained when the composition is less than or equal to the upper limit of the aforementioned range.

An organopolysiloxane for component (B) is a crosslinking agent for the present composition. Although the molecular structure of component (B) is not limited, the molecular structure of component (B) is exemplified by linear, partially branching linear, branched chain-like, cyclic, and dendritic structures. The molecular structure of component (B) is preferably a linear, partially branching linear, or dendritic structure. No particular limitation is placed on the bonding position of the silicon-bonded hydrogen atoms in component (B). For example, the silicon-bonded hydrogen atoms in component (B) may be bonded to silicon atoms in the molecular chain, or may be bonded to terminal silicon atoms of the molecular chain, or may be bonded to silicon atoms at both such positions. Each silicon-bonded group other than hydrogen atom in component (B) is independently a group selected from alkyl groups, such as a methyl group, ethyl group, propyl group, cyclopentyl group, cyclohexyl group, or the like, and preferably is a methyl group.

Although no limitation is placed on the viscosity of component (B), the viscosity at 25° C. of component (B) is preferably in the range of 1 to 10,000 mm² Is, and particularly preferably is in the range of 1 to 1,000 mm²/s.

Component (B) has preferably at least 0.7% by mass of silicon-bonded hydrogen atoms. Component (B) is particularly preferably an organopolysiloxane having at least 0.7% by mass of silicon-bonded hydrogen atoms and composed of SiO_{4/2} units and HR³₂SiO_{1/2} units (in the formula, each R³ is independently a group selected from alkyl group having 1 to 10 carbon atoms such as a methyl group, ethyl group, propyl group, cyclopentyl group, cyclohexyl group, or the like, and preferably is a methyl group), or component (B) is particularly preferably a linear organopolysiloxane having at least 0.7% by mass of silicon-bonded hydrogen atoms, wherein each silicon-bonded group other than hydrogen atom is independently group selected from alkyl groups having 1 to 10 carbon atoms.

This type of component (B) is exemplified by dimethylsiloxane-methylhydrogensiloxane copolymers having both molecular chain terminals capped by dimethylhydrogensiloxy groups, methylhydrogenpolysiloxane having both molecular chain terminals capped by trimethylsiloxy groups, dimethylsiloxane-methylhydrogensiloxane copolymers having both molecular chain terminals capped by trimethylsiloxy groups, organopolysiloxanes composed of SiO_{4/2} units and H(CH₃)₂SiO_{1/2} units, organopolysiloxanes composed of SiO₄₁₂ units, H(CH₃)₂SiO_{1/2} units, and (CH₃)₃SiO_{1/2} units, and mixtures of two or more such compounds.

The content of component (B) in the present composition, per 1 mol of total alkenyl groups in component (A), is in a range such that the silicon-bonded hydrogen atoms in component (B) is in a range from 0.5 to 5 mol, and preferably in a range from 0.7 to 2.5 mol. When the content of component (B) is greater than or equal to the lower limit of the aforementioned range, a composition is obtained that has preferred curability. On the other hand, when the content of component (B) is less than or equal to the upper limit of the aforementioned range, a cured product is obtained that has preferred thermal resistance.

Component (C) is used for lowering surface tackiness and lowering friction coefficient of the cured product obtained from the composition of the present invention, and is a linear dialkyl polysiloxane having alkenyl groups at both molecular chain terminals. Component (C) has a linear structure composed of repeated diorganosiloxane units (D units), normally about 2 to 20 units, preferably about 4 to 18 units, and further preferably about 6 to 11 units. The viscosity at 25° C. of component (C) is within the range of 2 to 10 mm²/s, and preferably is in the range of 3 to 8 mm²/s. The aforementioned alkenyl group preferably is an alkenyl group having 2 to 10 carbon atoms, and particularly preferably is a vinyl group.

In the present composition, the content of component (C) relative to 100 parts by mass of component (A) is within the range of 0.5 to 12 parts by mass, and preferably is in the range of 0.5 to 10 parts by mass. When the content of component (C) is greater than or equal to the lower limit of the aforementioned range, a cured product is obtained that has low surface tackiness. On the other hand, there is resistance to bleeding out of component (C) from the cured product if the content of component (C) is less than or equal to the upper limit of the aforementioned range.

A hydrosilylation-reaction catalyst for component (D) is a catalyst for accelerating the curing of the present composition, and examples include platinum-based catalysts, rhodium-based catalysts, and palladium-based catalysts. Of these, platinum-based catalysts are preferable. This platinum-based catalyst is a platinum-based compound exemplified by platinum fine powder, platinum black, platinum-supporting silica fine powder, platinum-supporting activated carbon, chloroplatinic acid, chloroplatinic acid alcohol solutions, olefin complexes of platinum, alkenylsiloxane complexes of platinum, or the like.

The amount of component (D) in the present composition is a catalytic amount. No particular limitation is placed on the amount of component (D) as long as the amount is capable of curing the present composition. Specifically, the amount of component (D) in the present composition is preferably in the range of 0.01 to 1,000 ppm by mass based on the metal atoms in this catalyst. When the content of component (D) is greater than or equal to the lower limit of the aforementioned range, a composition is obtained that has sufficient curability. On the other hand, when this content is less than or equal to the upper limit of the aforementioned range, there is little concern for coloration of the obtained cured product.

In addition to components (A) to (D), other desired components may be suitably added to the present composition. A reaction retardant may be added as such a desired component in order to adjust the speed of curing of the present composition. The reaction retardant is exemplified by alkyne alcohols such as 2-methyl-3-butyn-2-ol, 3,5-dimethyl-1-hexyn-3-ol, 1-ethynylcyclohexan-1-ol, 2-phenyl-3-butyn-2-ol, or the like; enyne compounds such as 3-methyl-3-penten-1-yne, 3,5-dimethyl-3-hexen-1-yne, or the like; 1,3,5,7-tetramethyl-1,3,5,7-tetravinylcyclotetrasiloxane, 1,3,5,7-tetramethyl-1,3,5,7-tetrahexenylcyclotetrasiloxane, benzotriazole, or the like. No limitation is placed on the content of this reaction retardant in the present composition, and the reaction retardant may be selected appropriately according to the molding method and curing conditions. Generally the content of this reaction retardant in the present composition is preferably within the range of 10 to 5,000 ppm by mass.

As long as the object of the present invention is not impeded, other components may be blended in the present composition, as exemplified by adhesion promotion agents, fire retardants, inorganic fillers, antistatic agents, or the like.

Although no particular limitation is placed on the viscosity at 25° C. of the present composition, from the standpoints of handling and processability (i.e. moldability, pouring ability, ease of deaeration, or the like), the viscosity is preferably in the range of 100 to 10,000 mPa·s, and particularly preferably is in the range of 1,000 to 7,000 mPa·s.

Moreover, it is possible to form the cured product by heating the present composition to a temperature of 100 to 250° C. Although no limitation is placed on the hardness of this cured product, in the case of measurement in accordance with JIS K 6253, the type A durometer hardness as stipulated in JIS K 6253 is preferably greater than or equal to 60 and less than or equal to 95, and further preferably is greater than or equal to 65 and less than or equal to 95.

The method for producing the semiconductor device and the semiconductor device of the present invention will be explained next in detail.

The method for producing the semiconductor device of the present invention is characterized as including a step of sealing a semiconductor element by the aforementioned curable silicone composition. In particular, the sealing of the semiconductor device is preferably performed by the aforementioned curable silicone composition using compression molding. This type of the mothod for sealing semiconductor device is exeplified by the following steps:
(i) light emitting elements or light receiving elements are mounted on a support body;
(ii) a release film shaped to the same shape as cavities in a mold is attached to the mold, which has cavities positioned opposing the aforementioned elements;
(iii) a curable silicone composition is poured onto the aforementioned release film; and
(iv) thereafter, the aforementioned composition is molded in a state where the support body is compressed against the aforementioned mold to obtain the semiconductor devices sealed by the cured product.

According to the method of the present invention, the light emitting elements or light receiving elements mounted on the support body are sealed using the curable silicone composition, and a molding machine is used that is capable of imparting a desired shape to the cured product. However, any generally used molding machine may be used for this type of molding machine. This molding machine preferably has an air suction mechanism in order to attach the release film to the cavities of the mold of the molding machine. This air suction mechanism is used for causing attachment of the aforementioned release film to the cavity of the mold during curing and molding of the curable silicone composition. After curing and molding of the composition, the air suction mechanism operates by feeding air to aid in the release the release film from the mold and to make the molded product readily removable from the mold.

Figures will be used to explain the present method. FIG. 1 is a partial cross-sectional drawing showing the semiconductor devices prior to sealing by use of the cured product of the silicone composition (parts farther right than the right end in FIG. 1 have been omitted, similarly to the below described figures). In FIG. 1, LED chips 2 are mounted on a support body by die bonding adhesive or the like. An external lead or a circuit (neither is illustrated) formed on the surface of this support body 1 is electrically connected by a bonding wire 3 to the aforementioned LED chip 2.

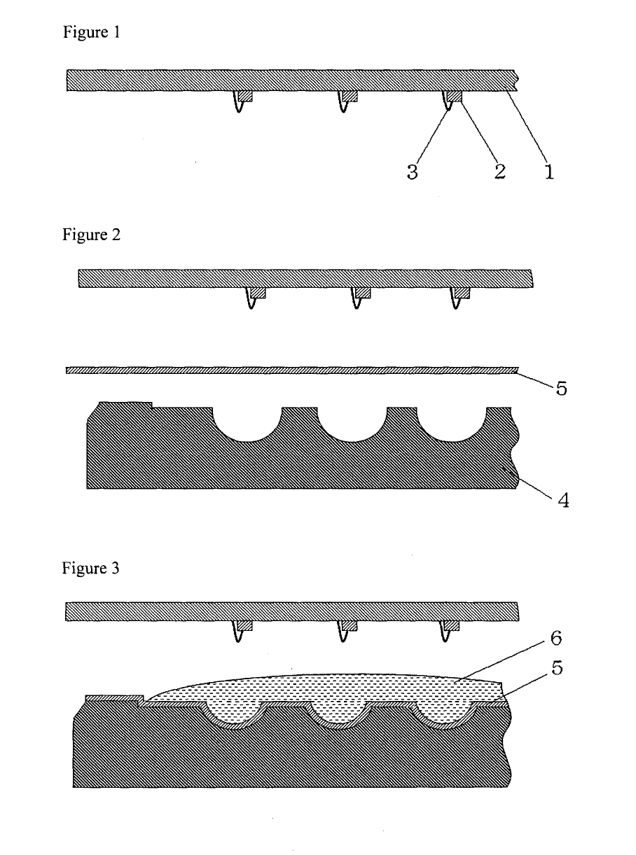

FIG. 2 is a partial cross-sectional drawing showing conditions prior to filling using the curable silicone composition. The support body 1 carrying the LED chips 2 is disposed opposite to the positions of the cavities of the mold 4. Thereafter, a release film 5 is fed between the support body 1 and the mold 4, and the release film is attached to the cavities of the mold by an air suction mechanism (not illustrated) arranged in the mold 4. FIG. 3 is a partial cross-sectional drawing of conditions immediately after feeding of the curable silicone composition 6 to the mold 4 covered by the release film 5.

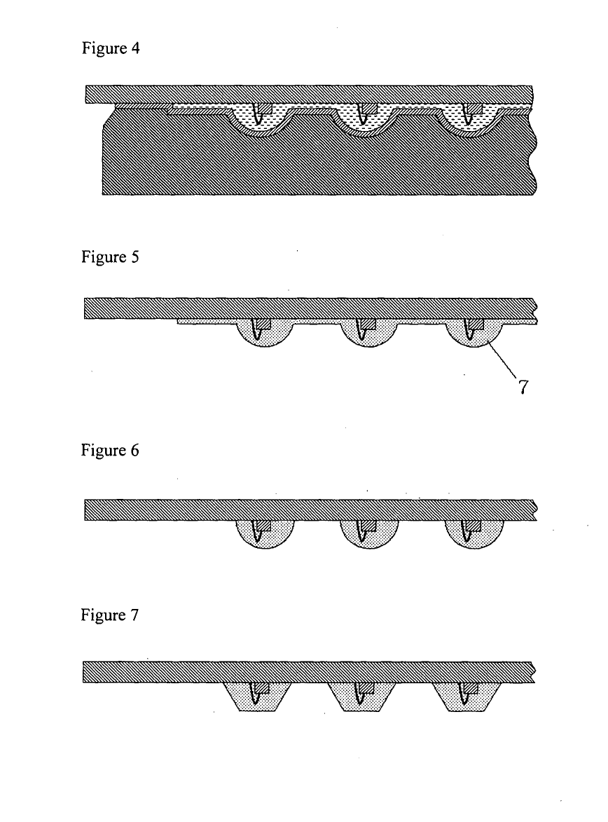

FIG. 4 is a partial cross-sectional drawing showing conditions during molding and curing of the curable silicone composition. By compression of the support body 1 against the mold 4, the release film 5 is sandwiched between the support body 1 and the mold 4, the peripheral part of the region sealed by the silicone composition is reliably sealed off, and it is possible to prevent leakage of the aforementioned composition.

This type of release film 5 may be readily attached to the mold by air suction or the like, and the release film has heat resistance for the curing temperature of the curable silicone composition. This type of release film is exemplified by fluoro resin films such as polytetrafluorotriethylene resin (PTFE) film, ethylene-tetrafluoroethylene copolymer resin (ETFE) film, tetrafluorotriethylene-perfluoropropylene copolymer resin (FEP) film, polyvinylidene fluoride resin (PVDF) film, or the like; polyester resin films such as polyethylene terephthalate resin (PET) film or the like; and non-fluorine containing polyolefin resin films such as polypropylene resin (PP) film, cycloolefin copolymer resin (COC) film, or the like. Although no particular limitation is placed on thickness of this type of release film, thickness of the release film is preferably about 0.01 mm to 0.2 mm.

Any curing conditions capable of curing this composition may be used as the curing conditions for this curable silicone composition. Without particular limitation, such curing conditions are exemplified by a temperature preferably of 50 to 200° C., and particularly preferably 100 to 150° C., for a time period preferably of about 0.5 to 60 minutes, and particularly preferably of about 1 to 30 minutes. As may be required, secondary curing (post curing) may be performed for about 0.5 to 4 hours at a temperature of 150 to 200° C.

FIG. 6 is a partial cross-sectional drawing showing the optical devices of the present invention integrated with the convex lenses made of silicone. In FIG. 6, multiple LED chips are mounted on a single support body plate. However, individual semiconductor devices may be produced by dicing of this support body using a blade dicing, laser dicing, or the like.

### EXAMPLES

The curable silicone composition, the method for producing a semiconductor device, and the semiconductor device of the present invention will be explained in further detail by use of practical examples and comparative examples. Note that the viscosity in the practical examples is the value at 25° C. With regards to the term “viscosity” in the present specification, kinematic viscosity (mm²/s units) is measured based on JIS Z 8803 using a capillary tube viscometer. On the other hand, viscosity (mPa·s units) is the value measured using a rotary viscometer. Moreover, the properties of the cured product were measured as follows.

### [Hardness of Cured Product]

The curable silicone composition was heated at 150° C. for 1 hour to produce the cured product. The hardness of the cured product was measured using a type A durometer specified in JIS K 6253.

### [Dynamic Friction Coefficient of Cured Product]

A 1 mm thick sheet-like cured product was produced by 1 hour of heating of the curable silicone composition at 150° C. This sheet-like cured product was set in a TRIBOGEAR type 14DR surface measurement instrument (manufactured by Shinto Scientific Co., Ltd.). While applying a load of 200 g using a ball indenter, the ball indenter was slid in the horizontal direction at a speed of 2,000 mm/minute, and the dynamic friction coefficient (μk) was measured.

### [Adhered Dust Amount of Cured Product]

The curable silicone composition was heated for 1 hour at 150° C. to produce a block-like 5 mm square cured product. Dyneon (registered trademark) TF Micropowder TF9205 (8 μm average particle diameter, manufactured by Sumitomo 3M Ltd.) was adhered to this block-like cured product. Blown air was used to blow away excess powder from the powder-adhered sample, and the amount of remaining adhered powder was measured to determine the amount of adhered powder.

Moreover, the semiconductor device was produced in the following manner.

### [Method for Producing Semiconductor Device (1)]

The curable silicone composition was used to seal semiconductor elements by the compression molding method. That is to say, a compression molding apparatus was prepared, and the attached upper die and lower die were heated to 130° C. A die out of which a dome shape was carved was used as the lower die. A substrate on which an LED chip was mounted was set in the upper die so that the LED chip faced downward. Ethylene-tetrafluoroethylene copolymer resin (ETFE) release film (AFLEX 50LM) was set on the lower die, and the release film was attached to the lower die using air suction. After pouring the curable silicone composition on the release film, the upper die and the lower die were positioned together, and the silicone composition was pressure molded for 3 minutes by application of a load of 3 MPa at 130° C. Thereafter, the substrate sealed by the silicone resin was removed from the mold, and the assembly was heated at 150° C. for 1 hour to cure the curable silicone composition. Dyneon (registered trademark) TF Micropowder TF9205 (8 μm average particle diameter, manufactured by Sumitomo 3M Ltd.) was sprinkled on the obtained cured product. Thereafter, blown air was used to blow away excess powder adhered to the aforementioned cured product, and the adhesive state of the remnant powder was visually observed. The observation of adhered powder was indicated by “×”, and the lack of observed adhered power was indicated by “∘”.

### [Method for Producing Semiconductor Device (2)]

The curable silicone composition was used to seal semiconductor elements using the compression molding method. That is to say, a compression molding apparatus was prepared, and the attached upper die and lower die were heated to 130° C. For the lower die, a mold was used that arrayed 100 dome-shaped moldings as 10 columns and 10 rows. A substrate carrying LEDs arranged in 10 rows and 10 columns so that each dome would be able to seal an LED chip was set against the upper die so that the LED chips faced downward. Ethylene-tetrafluoroethylene copolymer resin (ETFE) release film (AFLEX 50LM) was set above the lower die, and air suction was used to suck and attach the release film to the lower die. After pouring of the curable silicone composition on the release film, the upper die and lower die were fit together, and with the substrate in the sandwiched state, the silicone composition was compression molded for 3 minutes using a load of 3 MPa at 130° C. Thereafter, substrate sealed by the silicone resin was removed from the mold, and the substrate was heat treated for 1 hour in an oven at 150° C. Semiconductor devices were obtained that were sealed by the curable silicone compositions of Practical Example 1 and Comparative Example 1, which had flat parts and dome shapes thereon. Dyneon (registered trademark) TF Micropowder TF9205 (8 μm average particle diameter, manufactured by Sumitomo 3M Ltd.) was sprinkled on the obtained cured product. Thereafter, excess powder adhered to the silicone cured product was blown away by air blowing, and the adhesion state of the remaining powder was observed by optical microscope. The observation of adhered powder was indicated by “×”, while if adhered powder was not observed, this was indicated by “∘”.

### [Method for Producing Semiconductor Device (3)]

The flat part of the LED device resin sealed using the aforementioned method for producing semiconductor device (2) was diced at a feed speed of 3 mm/second by using a DAD 651 dicing device manufactured by Disco Corp. and a blade (B1A862SS) manufactured by Disco Corp., thereby producing separate semiconductor devices. Thereafter, the devices were washed using a spinner washing apparatus and were dried. The surface of the cured silicone resin sealing the obtained LED device was measured by optical microscope. The observation of cutting dust attachment was indicated by “×”, while if cutting dust was not observed, this was indicated by “∘”.

### Practical Examples 1 and 2 and Comparative Examples 1 to 8

Curable silicone compositions were prepared by homogeneously mixing the following components at the compounded amounts shown in table 1. Cured products of these curable silicone compositions were produced and were evaluated in the aforementioned manner. Moreover, these curable silicone compositions were used to produce semiconductor devices by the aforementioned methods (1) to (3). These results were shown in Table 1.
Component (A-1-1): Dimethylpolysiloxane capped at both molecular terminals with dimethylvinylsiloxy groups and having a viscosity of 360 mPa·s (vinyl group content=0.44% by mass)
Component (A-1-2): Dimethylpolysiloxane capped at both molecular terminals with dimethylvinylsiloxy groups and having a viscosity of 11,000 mPa·s (vinyl group content=0.14% by mass)
Component (A-1-3): Dimethylpolysiloxane capped at both molecular terminals with dimethylvinylsiloxy groups and having a viscosity of 65 mPa·s (vinyl group content=1.5% by mass)
Component (A-2-1): Organopolysiloxane resin having a mass average molecular weight of about 5,500 and represented by the following average unit formula (vinyl group content=3.4% by mass).

[(CH₃)₂CH₂═CHSiO_{1/2}]_{0.13}[(C₃)₃SiO_{1/2}]_{0.45}(SiO_{4/2})_{0.42}
Component (A-2-2): Organopolysiloxane having a mass average molecular weight of about 20,000 and represented by the following average unit formula (vinyl group content=4.2% by mass).

[(CH₃)₂CH₂═CHSiO_{1/2}]_{0.15}[(CH₃)₃SiO_{1/2}]_{0.38}(SiO_{4/2})_{0.47}
Component (B-1): Organopolysiloxane having a dynamic viscosity of 18 mm²/s and represented by the following average unit formula (silicon-bonded hydrogen atom content=about 0.97% by mass).

[H(CH₃)₂SiO_{1/2}]₈(SiO_{4/2})₄
Component (B-2): Methylhydrogensiloxane copolymer capped at both molecular terminals with trimethylsiloxy groups and having a kinematic viscosity of 5 mm²/s (content of silicon-bonded hydrogen atoms: approximately 1.4% by mass)
Component (B-3): Polymethylhydrogensiloxane capped at both molecular terminals with trimethylsiloxy groups and having a kinematic viscosity of 21 mm²/s (content of the silicon-bonded hydrogen atoms=about 1.57% by mass).
Component (B-4): Methylhydrogencyclosiloxane having a kinematic viscosity of 1 mm²/s and represented by the following average composition formula (silicon-bonded hydrogen atom content=about 1.66% by mass).

[H(CH₃)SiO]_{4.9}
Component (C-1): Dimethylsiloxane polymer capped at both molecular terminals by dimethylvinylsiloxy groups and having a kinematic viscosity of 5 mm²/s (vinyl group content=about 7.7% by mass).
Component (C-2): Methylvinylcyclosiloxane having a kinematic viscosity of 3.1 mm²/s and represented by the following average composition formula.

[(CH₃)CH₂═CHSiO]₄
Component (C-3): 1,3-divinyltetramethyldisiloxane that has a kinematic viscosity of 2 mm²/s.
Component (C-4): Hexamethyldisiloxane that has a kinematic viscosity of 0.65 mm²/s.
Component (D-1): 1,3-divinyltetramethyldisiloxane solution of 1,3-divinyltetramethyldisiloxane complex of platinum (platinum metal content=about 4,000 ppm).
Component (E-1); 1-ethynylcyclohexan-1-ol

TABLE 1

| | | Present invention | | Comparative Examples | | |
|---|---|---|---|---|---|---|
| | | Practical | Practical | Comparative | Comparative | Comparative |
| | | Example 1 | Example 2 | Example 1 | Example 2 | Example 3 |
| Curable silicone | Component (A-1-1) | 43 | 35 | 43 | 43 | 43 |
| composition | Component (A-1-2) | — | — | — | — | — |
| (parts by mass) | Component (A-1-3) | — | — | — | — | — |
| | Component (A-2-1) | 57 | 65 | 57 | 57 | 57 |
| | Component (A-2-2) | — | — | — | — | — |
| | Component (B-1) | 3.0 | — | 3.0 | 3.5 | 3.5 |
| | Component (B-2) | 3.0 | — | 3.0 | 3.5 | 3.5 |
| | Component (B-3) | — | — | — | — | — |
| | Component (B-4) | — | 13.0 | — | — | — |
| | Component (C-1) | 1.1 | 9.0 | — | — | — |
| | Component (C-2) | — | — | — | 1.1 | — |
| | Component (C-3) | — | — | — | — | 1.1 |
| | Component (C-4) | — | — | — | — | — |
| | Component (D-1) | 0.09 | 0.10 | 0.09 | 0.09 | 0.09 |
| | Component (E-1) | 0.06 | 0.05 | 0.06 | 0.06 | 0.06 |

| SiH/Vi* | | 0.9 | 1.9 | 0.9 | 0.9 | 0.9 |
|---|---|---|---|---|---|---|
| Cured product | Hardness | 82 | 68 | 81 | 82 | 83 |
| | Dynamic | 0.15 | 0.18 | 0.72 | 0.68 | 0.49 |
| | coefficient of | | | | | |
| | friction (μk) | | | | | |
| | Adhered dust | 0.3 | 0.3 | 0.6 | 0.2 | 0.3 |
| | amount (mg) | | | | | |
| Semiconductor | Method (1) | ∘ | ∘ | x | x | x |
| device external | Method (2) | ∘ | ∘ | x | x | x |
| visual appearance | Method (3) | ∘ | ∘ | x | x | x |

| | | Comparative Examples | | | | |
|---|---|---|---|---|---|---|
| | | Comparative | Comparative | Comparative | Comparative | Comparative |
| | | Example 4 | Example 5 | Example 6 | Example 7 | Example 8 |
| Curable silicone | Component (A-1-1) | 43 | 43 | 43 | — | 43 |
| composition | Component (A-1-2) | — | — | — | 72 | — |
| (parts by mass) | Component (A-1-3) | — | — | 1.1 | — | — |
| | Component (A-2-1) | 57 | 57 | 57 | — | 57 |
| | Component (A-2-2) | — | — | — | 28 | — |
| | Component (B-1) | 3.0 | 2.4 | 3.0 | — | 5.0 |
| | Component (B-2) | 3.0 | 2.4 | 3.0 | — | 5.0 |
| | Component (B-3) | — | — | — | 5.0 | — |
| | Component (B-4) | — | 1.1 | — | — | — |
| | Component (C-1) | — | — | — | 9.6 | 15.0 |
| | Component (C-2) | — | — | — | — | — |
| | Component (C-3) | — | — | — | — | — |
| | Component (C-4) | 1.1 | — | — | — | — |
| | Component (D-1) | 0.09 | 0.09 | 0.09 | 0.13 | 0.09 |
| | Component (E-1) | 0.06 | 0.06 | 0.06 | 0.10 | 0.06 |

| SiH/Vi* | | 0.9 | 0.9 | 0.9 | 1.0 | 1.0 |
|---|---|---|---|---|---|---|
| Cured product | Hardness | 82 | 88 | 82 | 73 | 85 |
| | Dynamic | 0.38 | 0.28 | 0.71 | 0.72 | 0.82 |
| | coefficient of | | | | | |
| | friction (μk) | | | | | |
| | Adhered dust | 0.5 | 0.5 | 0.5 | 0.8 | 0.8 |
| | amount (mg) | | | | | |
| Semiconductor | Method (1) | x | x | x | x | x |
| device external | Method (2) | x | x | x | x | x |
| visual appearance | Method (3) | x | x | x | x | x |

*In the table, SiH/Vi indicates the number of moles of total silicon-bonded hydrogen atoms in components (B-1) to (B-4) per 1 mole of the total vinyl groups in components (A-1-1) to (A-2-2) in each curable silicone composition.

### INDUSTRIAL APPLICABILITY

The curable silicone composition of the present invention forms a cured product that has low surface tackiness and has a low coefficient of friction. Thus the curable silicone composition is useful as a sealing agent for semiconductor elements such as light emitting diodes (LED), semiconductor lasers, photodiodes, phototransistors, solid state imaging elements, light emmiting elements and light receiving elements used for photocouplers, or the like.

### DESCRIPTION OF SYMBOLS

1 Support body

2 LED chip

3 Bonding wire

4 Mold

5 Release film

6 Curable silicone composition

7 Cured product

1. A curable silicone composition comprising:
(A) 100 parts by mass of an organopolysiloxane composed of:
(A-1) 30 to 70% by mass of a linear organopolysiloxane having a viscosity at 25° C. of 10 to 100,000 mPa·s, having at least two silicon-bonded alkenyl groups in a molecule, and each silicon-bonded group other than alkenyl group being independently selected from alkyl groups with 1 to 10 carbon atoms, and
(A-2) 70 to 30% by mass of a resin-like organopolysiloxane having 1.5 to 5.0% by mass of alkenyl groups, and comprising SiO_{4/2} units, R¹₂R²SiO_{1/2} units, and R¹₃SiO_{1/2} units, wherein each R¹ is independently a group selected from alkyl groups with 1 to 10 carbon atoms, and R² is an alkenyl group;
(B) an organopolysiloxane having at least two silicon-bonded hydrogen atoms in a molecule, and each silicon-bonded group other than hydrogen atom being independently selected from alkyl groups with 1 to 10 carbon atoms, in such an amount that the content of silicon-bonded hydrogen atoms contained in component (B) to 1 mole of total alkenyl groups contained in component (A) is in the range of 0.5 to 5 moles;
(C) 0.5 to 12 parts by mass of a linear dialkyl polysiloxane having a viscosity at 25° C. of 2 to 10 mm²/s and having alkenyl groups capping both molecular chain terminals; and
(D) a catalytic amount of hydrosilylation reaction catalyst.

2. The curable silicone composition according to claim 1, wherein component (A-2) is a resin-like organopolysiloxane having a total of 0.5 to 1.4 moles of the R¹₂R²SiO_{1/2} units and the R¹₃SiO_{1/2} units per 1 mole of the SiO4/2 units.

3. The curable silicone composition according to claim 1, wherein a cured product obtained by curing the composition has a type A durometer hardness measured in accordance with JIS K 6253 of greater than or equal to 60 and less than or equal to 95.

4. A method for producing a semiconductor device comprising a step of sealing a semiconductor element using the curable silicone composition according to claim 1.

5. The method for producing a semiconductor device according to claim 4, further comprising a step of sealing the semiconductor element with the curable silicone composition by compression molding.

6. The method for producing the semiconductor device according to claim 4, further comprising a step of dicing the semiconductor device by a blade after the semiconductor device is sealed with the curable silicone composition, to produce individual semiconductor devices.

7. A semiconductor device obtained by the method according to claim 4.

8. The curable silicone composition according to claim 2, wherein a cured product obtained by curing the composition has a type A durometer hardness measured in accordance with JIS K 6253 of greater than or equal to 60 and less than or equal to 95.

9. A method for producing a semiconductor device comprising a step of sealing a semiconductor element using the curable silicone composition according to claim 2.

10. A method for producing a semiconductor device comprising a step of sealing a semiconductor element using the curable silicone composition according to claim 3.

11. A method for producing a semiconductor device comprising a step of sealing a semiconductor element using the curable silicone composition according to claim 8.
